(19) United States
(12) Patent Application Publication
(10) Pub. No.: US 2016/0093625 A1
(43) Pub. Date: Mar. 31, 2016

(54) Method to Improve DRAM Performance

(71) Applicant: Intermolecular, Inc., San Jose, CA (US)

(72) Inventors: Xiangxin Rui, Campbell, CA (US); Imran Hashim, Saratoga, CA (US); Prashant B. Phatak, San Jose, CA (US)

(21) Appl. No.: 14/502,728

(22) Filed: Sep. 30, 2014

(51) Int. Cl. H01L 27/108; H01L 49/02

(52) U.S. Cl. CPC H01L 27/10805; H01L 28/75

(57) ABSTRACT

A first electrode layer for a Metal-Insulator-Metal (MIM) DRAM capacitor is formed wherein the first electrode layer contains a conductive base layer and conductive metal oxide layer. The dielectric layer may include zirconium oxide or doped zirconium oxide. In some embodiments, the conductive metal oxide layer includes niobium oxide.

### FIELD OF THE DISCLOSURE

The present disclosure relates generally to the use of non-noble metal electrodes in capacitors used in Dynamic Random Access Memory (DRAM) devices.

### BACKGROUND OF THE DISCLOSURE

Dynamic Random Access Memory utilizes capacitors to store bits of information within an integrated circuit. A capacitor is formed by placing a dielectric material between two electrodes formed from conductive materials. A capacitor's ability to hold electrical charge (i.e., capacitance) is a function of the surface area of the capacitor plates A, the distance between the capacitor plates d (i.e. the physical thickness of the dielectric layer), and the relative dielectric constant or k-value of the dielectric material. The capacitance is given by:

$$C = {κɛ}_{o} \frac{A}{d} \qquad ( Eqn . 1 )$$

where ∈ₒ represents the vacuum permittivity.

The dielectric constant is a measure of a material's polarizability. Therefore, the higher the dielectric constant of a material, the more electrical charge the capacitor can hold. Therefore, for a given desired capacitance, if the k-value of the dielectric is increased, the area of the capacitor can be decreased to maintain the same cell capacitance. Reducing the size of capacitors within the device is important for the miniaturization of integrated circuits. This allows the packing of millions (mega-bit (Mb)) or billions (giga-bit (Gb)) of memory cells into a single semiconductor device. The goal is to maintain a large cell capacitance (generally ˜10 to 25 fF) and a low leakage current (generally <10⁻⁷ A cm⁻²). The physical thickness of the dielectric layers in DRAM capacitors could not be reduced unlimitedly in order to avoid leakage current caused by tunneling mechanisms which exponentially increases as the thickness of the dielectric layer decreases.

Traditionally, SiO₂ has been used as the dielectric material and semiconducting materials (semiconductor-insulator-semiconductor [SIS] cell designs) have been used as the electrodes. The cell capacitance was maintained by increasing the area of the capacitor using very complex capacitor morphologies while also decreasing the thickness of the SiO₂ dielectric layer. Increases of the leakage current above the desired specifications have demanded the development of new capacitor geometries, new electrode materials, and new dielectric materials. Cell designs have migrated to metal-insulator-semiconductor (MIS) and now to metal-insulator-metal (MIM) cell designs for higher performance.

Typically, DRAM devices at technology nodes of 80 nm and below use MIM capacitors wherein the electrode materials are metals. These electrode materials generally have higher conductivities than the semiconductor electrode materials, higher work functions, exhibit improved stability over the semiconductor electrode materials, and exhibit reduced depletion effects. The electrode materials must have high conductivity to ensure fast device speeds. Representative examples of electrode materials for MIM capacitors are metals, conductive metal oxides, conductive metal silicides, conductive metal nitrides (i.e. TiN), or combinations thereof. MIM capacitors in these DRAM applications utilize insulating materials having a dielectric constant, or k-value, significantly higher than that of SiO₂ (k=3.9). For DRAM capacitors, the goal is to utilize dielectric materials with k values greater than about 20. Such materials are generally classified as high-k materials. Representative examples of high-k materials for MIM capacitors are non-conducting metal oxides, non-conducting metal nitrides, non-conducting metal silicates or combinations thereof. These dielectrics may also include additional dopant materials.

One class of high-k dielectric materials possessing the characteristics required for implementation in advanced DRAM capacitors are high-k metal oxide materials. Titanium oxide is a metal oxide dielectric material which displays significant promise in terms of serving as a high-k dielectric material for implementation in DRAM capacitors.

The dielectric constant of a dielectric material may be dependent upon the crystalline phase(s) of the material. For example, in the case of titanium oxide, the anatase crystalline phase of titanium oxide has a dielectric constant of approximately 40, while the rutile crystalline phase of titanium oxide can have a dielectric constant of approximately >80. Due to the higher-k value of the rutile-phase, it is desirable to produce titanium oxide based DRAM capacitors with the titanium oxide in the rutile-phase. The relative amounts of the anatase phase and the rutile phase can be determined from x-ray diffraction (XRD). From Eqn. 1 above, a titanium oxide layer in the rutile-phase could be physically thicker and maintain the desired capacitance. The increased physical thickness is important for lowering the leakage current of the capacitor. The anatase phase will transition to the rutile phase at high temperatures (>8000). However, high temperature processes are undesirable in the manufacture of DRAM devices.

The crystal phase of an underlying layer can be used to influence the growth of a specific crystal phase of a subsequent material if their crystal structures are similar and their lattice constants are similar. This technique is well known in technologies such as epitaxial growth. The same concepts have been extended to the growth of thin films where the underlying layer can be used as a “template” to encourage the growth of a desired phase over other competing crystal phases.

Conductive metal oxides, conductive metal silicides, conductive metal nitrides, conductive metal carbides, or combinations thereof are examples of other classes of materials that may be suitable as DRAM capacitor electrodes. Generally, transition metals and their conductive binary compounds form good candidates as electrode materials. The transition metals exist in several oxidation states. Therefore, a wide variety of compounds are possible. Different compounds may have different crystal structures, electrical properties, etc. It is important to utilize the proper compound for the desired application.

In one example, molybdenum has several binary oxides, of which MoO₂ and MoO₃ are two examples. These two oxides of molybdenum have different properties. MoO₂ has shown great promise as an electrode material in DRAM capacitors. MoO₂ has a distorted rutile crystal structure and serves as an acceptable template to promote the deposition of the rutile-phase of TiO₂ as discussed above. MoO₂ also has a high work function (can be >5.0 eV depending on process history) which helps to minimize the leakage current of the DRAM device. However, oxygen-rich phases (MoO₂₊ₓ) degrade the performance of the MoO₂ electrode because they do not promote the deposition of the rutile-phase of TiO₂. For example, MoO₃ (the most oxygen-rich phase) has an orthorhombic crystal structure.

Generally, a deposited thin film may be amorphous, crystalline, or a mixture thereof. Furthermore, several different crystalline phases may exist. Therefore, processes (both deposition and post-treatment) must be developed to maximize the formation of crystalline MoO₂ and to minimize the presence of MoO₂₊ₓ phases. Deposition processes and post-treatment processes in a reducing atmosphere have been developed that allow crystalline MoO₂ to be used as the first electrode (i.e. bottom electrode) in MIM DRAM capacitors with titanium oxide or doped-titanium oxide high-k dielectric materials. Examples of the post-treatment process are further described in U.S. application Ser. No. 13/084,666 filed on Apr. 12, 2011, which is incorporated herein by reference for all purposes. Other conductive metal oxides that may be used as a template for the rutile phase of titanium oxide include the conductive compounds of molybdenum oxide, tungsten oxide, ruthenium oxide, iron oxide, iridium oxide, chromium oxide, manganese oxide, tin oxide, cobalt oxide, or nickel oxide.

As used herein, the phrase “conductive metal oxide” will be understood to include the typical stoichiometric metal oxides as well as conductive non-stoichiometric metal oxides wherein the oxygen to metal ratio is not equal to the stoichiometric ratio. As an example, “conductive molybdenum oxide” will include MoO₂ as well as those conductive molybdenum oxides wherein the oxygen to metal ratio is slightly greater than or slightly less than 2. Those skilled in the art will understand that metal-oxygen compounds that are slightly off of the stoichiometric ratio will also be conductive and will fall within the scope of the present disclosure. As used herein, the phrase “conductive metal oxide” will be understood to include metal oxide materials having a resistivity of less than about 10 Ωcm.

Therefore, there is a need to develop processes that allow the formation of a conductive metal oxide electrode layers (e.g. first electrode and/or second electrode) that can serve as a template for the rutile phase of titanium oxide (e.g. first electrode embodiments), and have high work function values to reduce the leakage current density through the device.

### SUMMARY OF THE DISCLOSURE

In some embodiments, a conductive metal oxide first electrode layer is formed as part of a MIM DRAM capacitor stack. In some embodiments, a metal oxide layer is formed as part of a bilayer first electrode of a MIM DRAM capacitor stack. A first electrode layer for a Metal-Insulator-Metal (MIM) DRAM capacitor is formed wherein the first electrode layer contains a conductive base layer and conductive metal oxide layer. The dielectric layer may include zirconium oxide or doped zirconium oxide. In some embodiments, the conductive metal oxide layer includes niobium oxide.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present disclosure can readily be understood by considering the following detailed description in conjunction with the accompanying drawings, in which:

FIG. 1 illustrates a flow chart illustrating a method for fabricating a DRAM capacitor stack in accordance with some embodiments.

FIG. 2 illustrates a simplified cross-sectional view of a DRAM capacitor stack fabricated in accordance with some embodiments.

FIG. 3 presents data for k value for different film stacks in accordance with some embodiments.

FIG. 4 presents data for leakage current density at +1V for different film stacks in accordance with some embodiments.

FIG. 5 illustrates a simplified cross-sectional view of a DRAM memory cell fabricated in accordance with some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a”, “an”, and “the” include plural referents unless the context clearly dictates otherwise. Thus, for example, reference to “a layer” also includes two or more layers, and so forth. As an example, those skilled in the art will understand that an “electrode layer” may include a single layer or may include a “bilayer” of two materials.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%.

As used herein, the term “substantially” generally refers to ±5% of a stated value.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, a material (e.g. a dielectric material or an electrode material) will be considered to be “crystalline” if it exhibits greater than or equal to 30% crystallinity as measured by a technique such as x-ray diffraction (XRD).

The term “substrate” as used herein may refer to any workpiece on which formation or treatment of material layers is desired. Non-limiting examples include silicon, germanium, silica, sapphire, zinc oxide, silicon carbide, aluminum nitride, gallium nitride, Spinel, silicon on oxide, silicon carbide on oxide, glass, gallium nitride, indium nitride, aluminum nitride, glasses, combinations or alloys thereof, and other solid materials.

As used herein, the notation “Mo—O” and “MoO” and “MoOₓ” will be understood to be equivalent and will be used interchangeably and will be understood to include a material containing these elements in any ratio. Where a specific composition is discussed, the atomic concentrations (or ranges) will be provided. The notation is extendable to other materials and other elemental combinations discussed herein.

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, the term “between” (when used with a range of values) will be understood to mean that both boundary values and any value between the boundaries can be within the scope of the range.

As used herein, the terms “first,” “second,” and other ordinals will be understood to provide differentiation only, rather than imposing any specific spatial or temporal order.

As used herein, the term “oxide” (of an element) will be understood to include additional components besides the element and oxygen, including but not limited to a dopant or alloy.

As used herein, the term “nitride” (of an element) will be understood to include additional components besides the element and nitrogen, including but not limited to a dopant or alloy.

Dopants can be added to the dielectric material to increase the k-value and/or decrease the leakage current. As used herein, the dopant may be electrically active or not electrically active. The definition excludes residues and impurities such as carbon, etc. that may be present in the material due to inefficiencies of the process or impurities in the precursor materials. The concentration of the dopant is one factor that affects the crystallinity of the dielectric material. Other factors that affect the crystallinity of the dielectric material comprise annealing time, annealing temperature, film thickness, etc. Generally, as the concentration of the dopant is increased, the crystallization temperature of the dielectric material increases.

The term “nanolaminate”, as used herein, will be understood to be defined as a material or layer that is formed from the deposition of a plurality of sub-layers. Typically, the sub-layers include different materials and the different sub-layers are alternated in a predetermined ratio of thicknesses and/or compositions.

As used herein, the term “Flash layer” will be understood to describe an additional layer inserted between the first (e.g. bottom) electrode layer and the dielectric layer.

As used herein, the term “Capping layer” will be understood to describe an additional layer inserted between the second (e.g. top) electrode layer and the dielectric layer.

As used herein, the term “Blocking layer” will be understood to describe an additional generic layer inserted either between the first (e.g. bottom) electrode layer and the dielectric layer, between the second (e.g. top) electrode layer and the dielectric layer, or both. As defined above, both “Flash layers” and “Capping layers” are examples of the more general “Blocking layer”.

As used herein, the term “Inert gas” will be understood to include noble gases (He, Ne, Ar, Kr, Xe) and, unless the text or context excludes it (e.g., by describing nitride formation as undesirable), nitrogen (N₂).

As used herein, the term “Monolayer” will be understood to include a single layer of atoms or molecules covering a surface, with substantially all available bonding sites satisfied and substantially all individual members of the adsorbed species in direct physical contact with the underlying surface.

As used herein, the term “Sub-monolayer” or “pre-wetting layer” will be understood to include a partial or incomplete monolayer; maximum thickness is one atom or molecule, but not all available bonding sites on the surface are covered, so that the average thickness is less than one atom or molecule.

As used herein, the term “Surface” will be understood to describe the boundary between the ambient environment and a feature of the substrate.

Leakage current in capacitor dielectric materials can be due to Schottky emission, Frenkel-Poole defects (e.g. oxygen vacancies (Vₒₓ) or grain boundaries), or Fowler-Nordheim tunneling. Schottky emission, also called thermionic emission, is a common mechanism and is the thermally activated flow of charge over an energy barrier whereby the effective barrier height of a MIM capacitor controls leakage current. The nominal barrier height is a function of the difference between the work function of the electrode and the electron affinity of the dielectric. The electron affinity of a dielectric is closely related to the conduction band offset of the dielectric. The Schottky emission behavior of a dielectric layer is generally determined by the properties of the dielectric/electrode interface. Frenkel-Poole emission allows the conduction of charges through a dielectric layer through the interaction with defect sites such as vacancies, grain boundaries, and the like. As such, the Frenkel-Poole emission behavior of a dielectric layer is generally determined by the dielectric layer's bulk properties. Fowler-Nordheim emission allows the conduction of charges through a dielectric layer through direct tunneling without any intermediary interaction with e.g. defects. As such, the Fowler-Nordheim emission behavior of a dielectric layer is generally determined by the physical thickness of the dielectric layer. This leakage current is a primary driving force in the adoption of high-k dielectric materials. The use of high-k materials allows the physical thickness of the dielectric layer to be as thick as possible while maintaining the required capacitance (see Eqn 1 above).

As discussed previously, materials with a high k value generally have a narrow band gap. The narrow band gap leads to high leakage current through the Schottky emission mechanism due to the low barrier height. The leakage current may be reduced through the use of a blocking layer that has a wider band gap. Some metal oxide materials have a high work function and may be suitable as blocking layers. These layers may be used at one or both electrodes of the capacitor stack to reduce the leakage current. The benefits of the blocking layers may be realized if they are thin (e.g. have a thickness of less than about 20 A) and are amorphous (e.g. are less than 30% crystalline after subsequent anneal steps). The blocking layers must be thick enough to lower the leakage current, but as thin as possible so that they do not decrease the k value of the capacitor stack and increase the EOT.

Zirconium oxide (or doped versions of zirconium oxide) is widely used as the dielectric material in DRAM MIM capacitors for technology nodes approaching the 1×nm node. As the technology has been extended to 20 nm and below, dielectric materials with a higher k value should be implemented. One approach would be to extend the use of zirconium oxide by increasing the k value. Zirconium oxide (or doped versions of zirconium oxide) exists in several different crystalline phases. The cubic phase exhibits a k value of about 37. The tetragonal phase exhibits a k value of about 47. In practice, deposited zirconium oxide films are mixed phases of cubic, tetragonal, and amorphous phases. Typical effective k values of about 30 are observed.

Niobium oxide can be added to zirconium oxide and has been found to stabilize the tetragonal phase. However, niobium oxide has a narrow band gap (e.g. about 3.5 eV) and will lead to an increase in the leakage current density of the dielectric material.

In some embodiments, niobium oxide is introduced as a “Flash layer” between the first (e.g. bottom) electrode layer and the dielectric layer in a capacitor stack. The niobium oxide flash layer can be very thin (e.g. between about 1 A and about 15 A) and will serve to stabilize the higher k value tetragonal phase of a zirconium oxide dielectric layer formed above the niobium oxide flash layer. The niobium oxide layer can be treated as part of the first electrode layer due to the narrow band gap of the niobium oxide and the thinness of the layer.

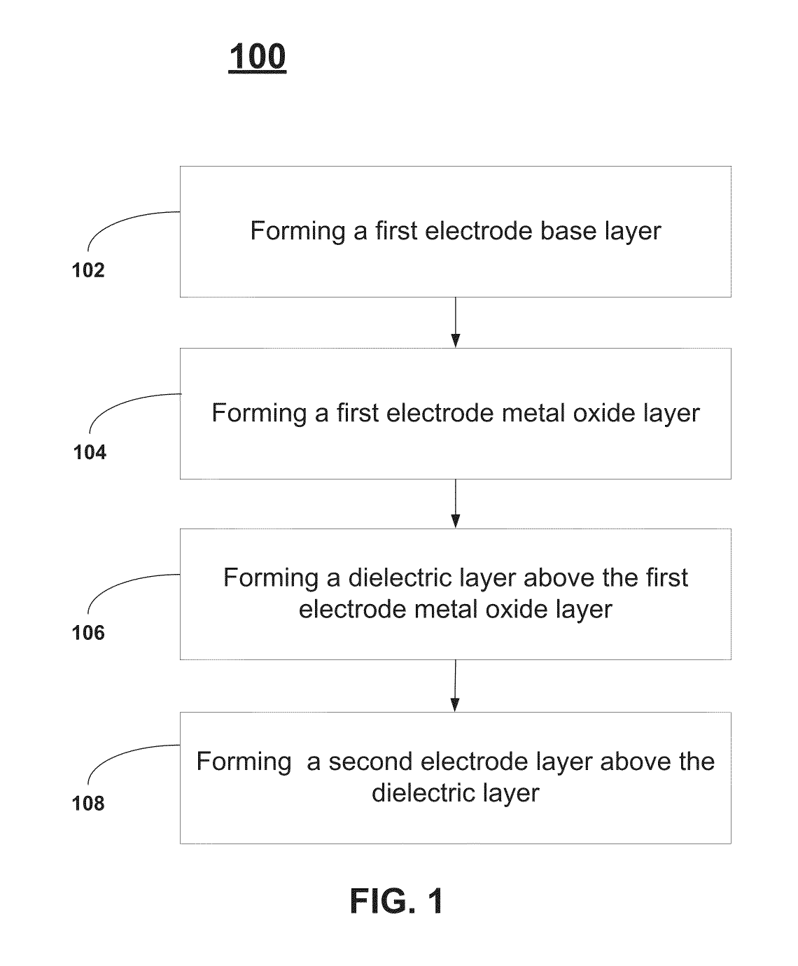

FIG. 1 describes a method, 100, for fabricating a DRAM capacitor stack. The capacitor stack includes a first electrode layer, a dielectric layer, and a second electrode layer. The first electrode layer may include a single layer or may include multiple layers as discussed previously. The initial step, 102, includes forming a first electrode base layer above a substrate. Examples of suitable first electrode base layers include metals, conductive metal oxides, conductive metal silicides, conductive metal nitrides, and combinations thereof. A particularly interesting class of materials for the first electrode base layer is the conductive metal nitrides. The next step, 104, includes forming a first electrode metal oxide layer (e.g. flash layer) above the first electrode base layer. Examples of such metal oxides include the compounds of cerium oxide, chromium oxide, europium oxide, iridium oxide, manganese oxide, molybdenum oxide, niobium oxide, ruthenium oxide, tin oxide, or tungsten oxide. Specific metal oxide materials of interest are the compounds of niobium oxide. Typically, metal oxide layers are deposited using atomic layer deposition (ALD) processes. The metal oxide layer may be deposited using an ALD process. Other deposition methods such as PVD and CVD may also be used. Together, the first electrode base layer and the first electrode metal oxide layer form the first electrode layer of the capacitor stack. The first electrode layer can then be subjected to an annealing process (not shown). The annealing process may include a reducing atmosphere, an oxidizing atmosphere, or a nutrual atmosphere. In some embodiments, the first electrode layer is annealed in a reducing atmosphere including between about 0 volume % and about 10 volume % hydrogen in nitrogen (or other inert gas) at a temperature between about 400 C and about 650 C for a time between about 1 millisecond and about 60 minutes. In some embodiments, the first electrode layer is annealed in an oxidizing atmosphere including between about 0 volume % and about 100 volume % oxygen in nitrogen (or other inert gas) at a temperature between about 300 C and about 600 C for a time between about 1 millisecond and about 60 minutes. The next step, 106, includes forming a dielectric layer above the first electrode layer. Optionally, the dielectric layer can then be subjected to a post dielectric anneal (PDA) treatment (not shown). The PDA step serves to crystallize the dielectric layer and/or fill oxygen vacancies. The next step, 108, includes forming a second electrode layer on the dielectric layer. The second electrode layer may include a single layer or may include multiple layers as discussed previously. Examples of suitable electrode materials include metals, conductive metal oxides, conductive metal silicides, conductive metal nitrides, and combinations thereof. Optionally, the capacitor stack can then be subjected to PMA treatment process in an reducing, oxidizing, or natural atmosphere, wherein the oxidizing atmosphere includes between 0% O₂ to 25% O₂ and at temperatures between 300 C to 600 C for between 1 millisecond to 60 minutes (not shown). Examples of the PDA and PMA treatments are further described in U.S. application Ser. No. 13/159,842 filed on Jun. 14, 2011, and is herein incorporated by reference for all purposes. Those skilled in the art will understand that other layers may be included in the capacitor stack. The benefits of the flash layer may be realized if they are thin (e.g. between about 1 A and about 15 A), and are amorphous (e.g. are less than 30% crystalline after subsequent anneal steps). The flash layers must be thick enough to lower the leakage current, but as thin as possible so that they do not decrease the k value of the capacitor stack and increase the EOT.

Those skilled in the art will appreciate that the formation of each of the first electrode layer, the dielectric layer, and the second electrode structure used in the MIM DRAM capacitor has been described using a generic ALD process. However, any of the variants of the generic ALD process may also be implemented. Common variants include plasma enhanced atomic layer deposition (PE-ALD), atomic vapor deposition (AVD), and ultraviolet assisted atomic layer deposition (UV-ALD), etc. Generally, because of the complex morphology of the DRAM capacitor structure, ALD, PE-ALD, AVD, or UV-ALD are preferred methods of formation. However, any of these techniques are suitable for forming each of the various layers discussed herein. Those skilled in the art will appreciate that the teachings described herein are not limited by the variant of the ALD technology used for the deposition process.

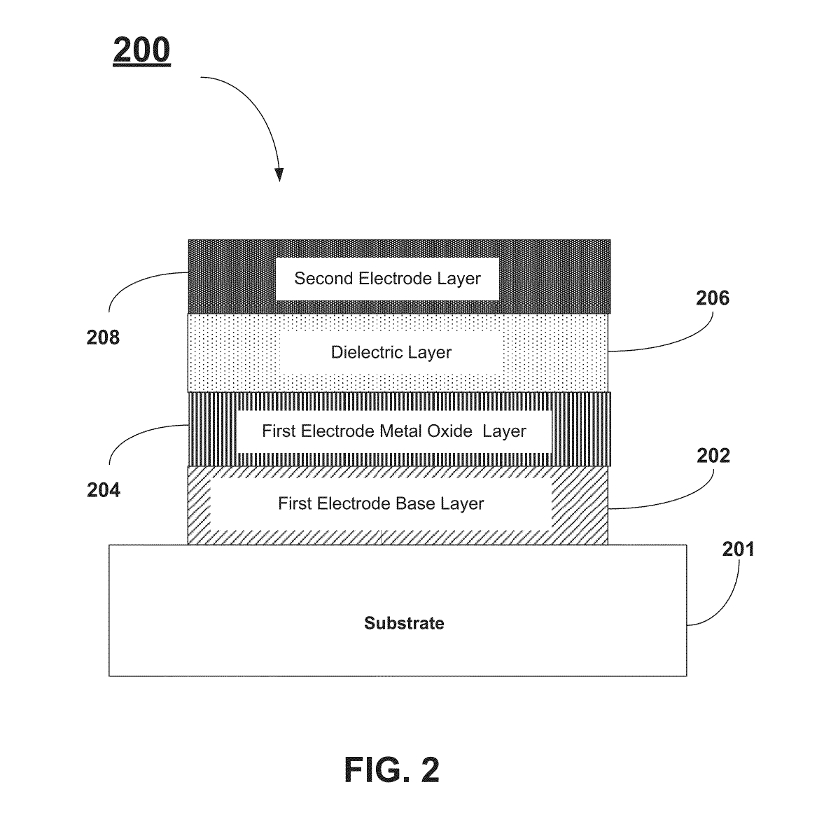

In FIGS. 2 and 6 below, a capacitor stack is illustrated using a simple planar structure. Those skilled in the art will appreciate that the description and teachings to follow can be readily applied to any simple or complex capacitor morphology. The drawings are for illustrative purposes only and do not limit the application of the present invention.

FIG. 2 illustrates a simple capacitor stack, 200, consistent with some embodiments. The capacitor stack includes a first electrode layer, a dielectric layer, and a second electrode layer. The first electrode layer may include a single layer or may include multiple layers as discussed previously. Using the method as outlined in FIG. 1 and described previously, first electrode base layer, 202, is formed above substrate, 201. Generally, the substrate has already received several processing steps in the manufacture of a full DRAM device. First electrode base layer, 202, includes one of metals, conductive metal oxides, conductive metal nitrides, conductive metal silicides, etc. In some embodiments, the conductive base layer includes one of ruthenium, platinum, titanium nitride, tantalum nitride, titanium-aluminum-nitride, tungsten, tungsten nitride, molybdenum, molybdenum nitride, or vanadium nitride. A particularly interesting class of materials for the first electrode base layer is the conductive metal nitrides. In some embodiments, the first electrode base layer includes titanium nitride. The first electrode base layer is typically formed using an ALD, CVD, or PVD technique. The first electrode base layer typically has a thickness between 5 nm and 50 nm, and preferably between 10 nm and 25 nm. In some embodiments, first electrode metal oxide layer (i.e. blocking layer or flash layer), 204, is formed above first electrode base layer, 202. Together, the first electrode base layer and the first electrode metal oxide layer form the first electrode layer of the capacitor stack. The metal oxide portion of the first electrode may be formed using an ALD process as discussed previously. The first electrode metal oxide layer typically has a thickness between 1 A and 15 A. In some embodiments, the first electrode metal oxide layer may include at least one of the compounds of cerium oxide, chromium oxide, europium oxide, iridium oxide, manganese oxide, molybdenum oxide, niobium oxide, ruthenium oxide, tin oxide, or tungsten oxide. Specific metal oxide materials of interest are the compounds of niobium oxide. The first electrode layer, (202 and 204), can be annealed (e.g. in a reducing atmosphere, an oxidizing atmosphere, or an natural atmosphere as discussed previously) to crystallize the layer.

In some embodiments, dielectric layer, 206, would then be formed above the first electrode metal oxide layer, 204. The dielectric layer is typically formed using an ALD, CVD, or PVD technique. The dielectric layer typically has a thickness between 5 nm and 10 nm, and preferably between 5 nm and 8 nm. A wide variety of dielectric materials have been targeted for use in DRAM capacitors. Examples of suitable dielectric materials include aluminum oxide, barium-strontium-titanate (BST), hafnium oxide, hafnium silicate, niobium oxide, lead-zirconium-titanate (PZT), a bilayer of silicon oxide and silicon nitride, silicon oxy-nitride, strontium-titanate (STO), tantalum oxide, titanium oxide, zirconium oxide or doped versions of the same. These dielectric materials may be formed as a single layer or may be formed as a hybrid or nanolaminate structure. In some embodiments, the dielectric layer includes zirconium oxide. In some embodiments, the dielectric layer includes doped zirconium oxide. Typical dopants for zirconium oxide include Al, Ce, Co, Er, Ga, Gd, Ge, Hf, In, La, Lu, Mg, Mn, Nd, Pr, Sc, Si, Sn, Sr, Ti, Y, or combinations thereof. Typically, dielectric layer, 206, is subjected to a PDA treatment before the formation of the second electrode layer as discussed previously.

In the next step, the second electrode layer, 208, is formed above dielectric layer, 206. The second electrode layer may include a single layer or may include multiple layers as discussed previously. The second electrode layer is typically formed using an ALD, CVD, or PVD technique. The second electrode layer typically has a thickness between 5 nm and 50 nm, and preferably between 10 nm and 25 nm. The second electrode layer includes one of metals, conductive metal oxides, conductive metal nitrides, conductive metal silicides, conductive metal carbides, or combinations thereof. Optionally, the capacitor stack can then be subjected to a PMA treatment process in an reducing, natural, or oxidizing atmosphere, wherein the oxidizing atmosphere includes between 0% O₂ to 25% O₂ and at temperatures between 300 C to 600 C for between 1 millisecond to 60 minutes (not shown). Those skilled in the art will understand that other layers may be included in the capacitor stack.

The benefits of the flash layer may be realized if they are thin (e.g. between about 1 A and about 15 A), are amorphous (e.g. are less than 30% crystalline after subsequent anneal steps). The blocking layers must be thick enough to lower the leakage current, but as thin as possible so that they do not decrease the k value of the capacitor stack and increase the EOT.

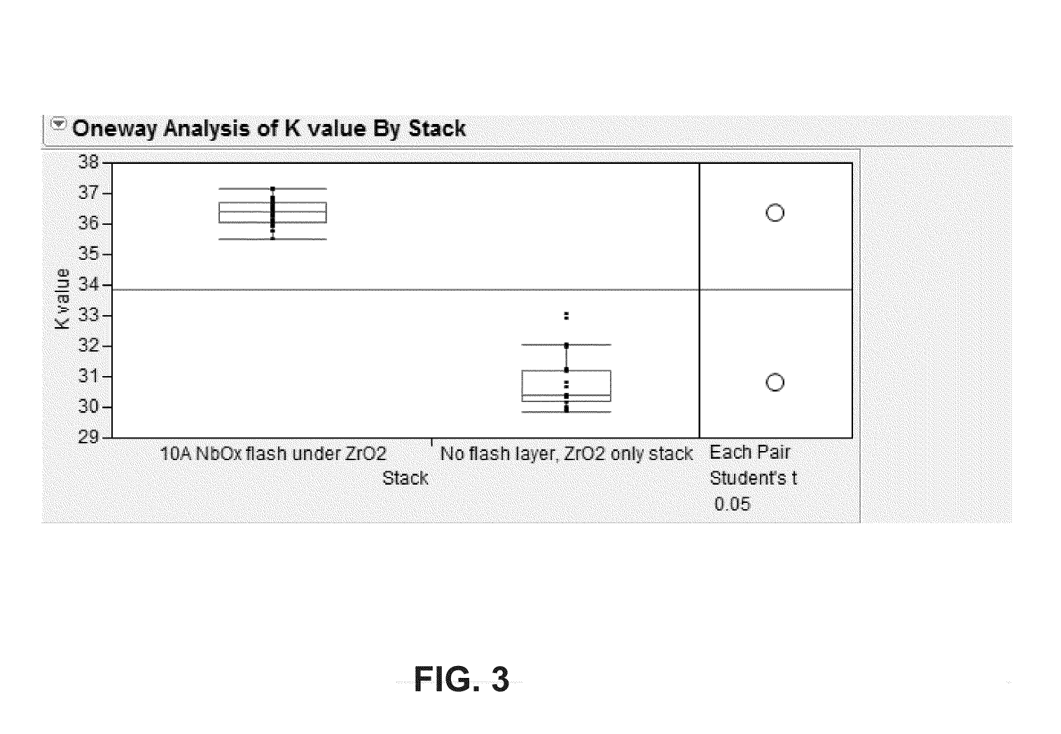

FIG. 3 presents data for k value for several capacitor stacks fabricated in accordance with some embodiments. All of the capacitor stacks included a first electrode base layer of about 50 nm of titanium nitride. The dielectric layer included zirconium oxide. The dielectric layer was formed in thicknesses between about 50 A and 70 A (e.g. 66 A). One set of samples (labeled “No Flash layer”) did not include a first electrode metal oxide layer. A second set of samples (labeled “10 A NbOx Flash”) included a first electrode metal oxide layer (i.e. blocking or flash layer) of 10 A of niobium oxide. All of the capacitor stacks included a second electrode layer of about 100 nm of titanium nitride. It is clear that samples without the first electrode metal oxide layer (i.e. “No Flash layer” samples) exhibited a lower k value. Without being bound by theory, the higher k value for the “10 A NbOx Flash” samples indicates that the higher k tetragonal phase of the zirconium oxide has been enhanced by the presence of the underlying niobium oxide flash layer. As discussed previously, k value can be increased by inserting a templating layer between the dielectric layer and the first electrode layer. Clearly, adding the niobium oxide layer between the dielectric layer and the first electrode layer increases the k value. The benefits of the flash layer may be realized if they are thin (e.g. have a thickness of less than about 15 A), and are amorphous (e.g. are less than 30% crystalline after subsequent anneal steps).

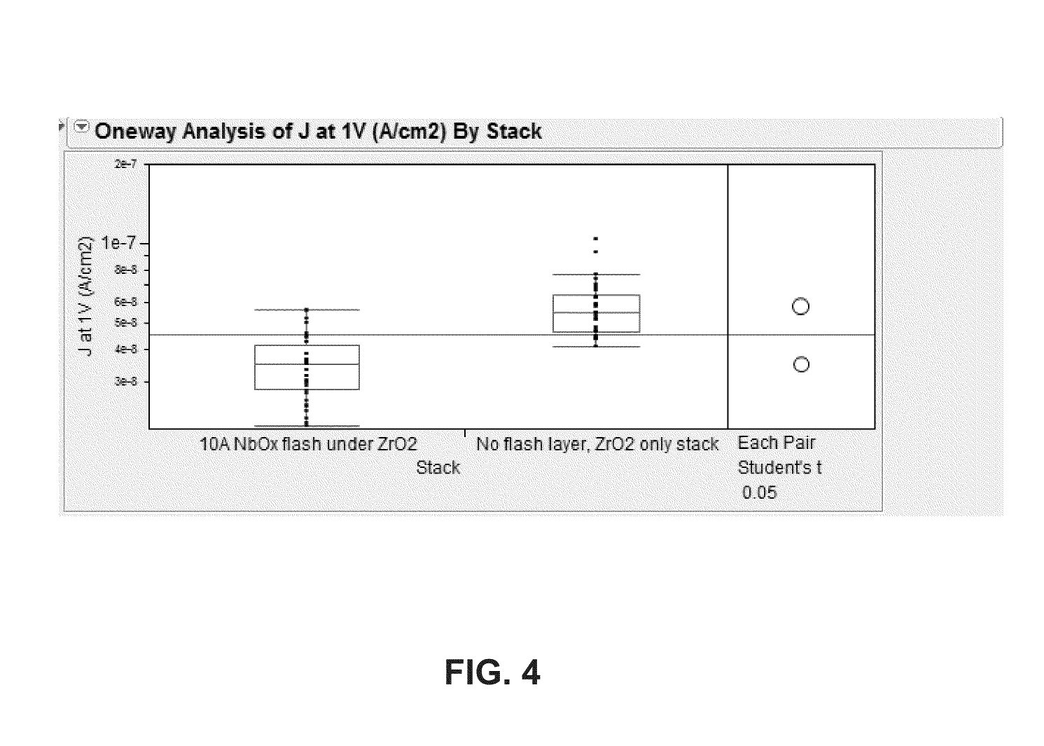

FIG. 4 presents data for leakage current density at +1V for several capacitor stacks fabricated in accordance with some embodiments. All of the capacitor stacks included a first electrode base layer of about 50 nm of titanium nitride. The dielectric layer included zirconium oxide. The dielectric layer was formed in thicknesses between about 50 A and 70 A (e.g. 66 A). One set of samples (labeled “No Flash layer”) did not include a first electrode metal oxide layer. A second set of samples (labeled “10 A NbOx Flash”) included a first electrode metal oxide layer (i.e. blocking or flash layer) of 10 A of niobium oxide. All of the capacitor stacks included a second electrode layer of about 100 nm of titanium nitride. It is clear that samples with the first electrode metal oxide layer (i.e. “10 A NbOx flash” samples) does not exhibit a higher leakage current density for positive bias. As used herein, “positive bias” will be understood to mean that the second electrode is held at a positive voltage relative to the first electrode. In the positive bias configuration, electrons will be injected into the capacitor through the first electrode. As used herein, “negative bias” will be understood to mean that the second electrode is held at a negative voltage relative to the first electrode. In the negative bias configuration, electrons will be injected into the capacitor through the second electrode. Without being bound by theory, the leakage current density for the “10 A NbOx Flash” samples under positive bias does not increase indicates that although NbOx has lower band gap than ZrOx (3.5 eV vs. 5.8 eV), NbOx flash layer is acted as a conductive layer and will not adversely affect the leakage of MIM cap stack. The benefits of the flash layer may be realized if they are thin (e.g. have a thickness of less than about 15 A), and are amorphous (e.g. are less than 30% crystalline after subsequent anneal steps). The flash layers must be thin enough to be a conductive layer.

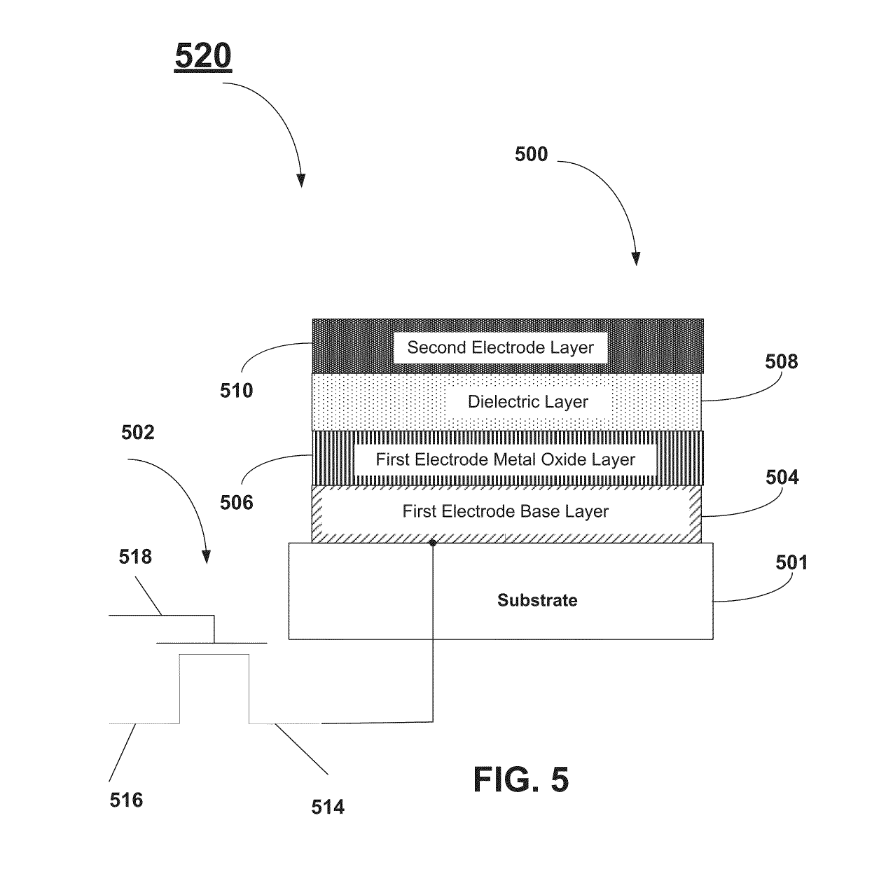

An example of a specific application of some embodiments is in the fabrication of capacitors used in the memory cells in DRAM devices. DRAM memory cells effectively use a capacitor to store charge for a period of time, with the charge being electronically “read” to determine whether a logical “one” or “zero” has been stored in the associated cell. Conventionally, a cell transistor is used to access the cell. The cell transistor is turned “on” in order to store data on each associated capacitor and is otherwise turned “off” to isolate the capacitor and preserve its charge. More complex DRAM cell structures exist, but this basic DRAM structure will be used for illustrating the application of this disclosure to capacitor manufacturing and to DRAM manufacturing. FIG. 5 is used to illustrate one DRAM cell, 520, manufactured using a first electrode structure as discussed previously. The cell, 520, is illustrated schematically to include two principle components, a cell capacitor stack, 500, and a cell transistor, 502. The cell transistor is usually constituted by a MOS transistor having a gate, 518, source, 514, and drain, 516. The gate is usually connected to a word line and one of the source or drain is connected to a bit line. The cell capacitor has a lower or storage electrode and an upper or plate electrode. The storage electrode is connected to the other of the source or drain and the plate electrode is connected to a reference potential conductor. The cell transistor is, when selected, turned “on” by an active level of the word line to read or write data from or into the cell capacitor via the bit line.

As was described previously, the cell capacitor stack, 500, includes a first electrode layer, a dielectric layer, and a second electrode layer. The first electrode layer may include a single layer or may include multiple layers as discussed previously. Using the method as outlined in FIG. 1 and described previously, first electrode base layer, 504, is formed above substrate, 501. Generally, the substrate has already received several processing steps in the manufacture of a full DRAM device. First electrode base layer, 504, includes one of metals, conductive metal oxides, conductive metal nitrides, conductive metal silicides, etc. In some embodiments, the conductive base layer includes one of ruthenium, platinum, titanium nitride, tantalum nitride, titanium-aluminum-nitride, tungsten, tungsten nitride, molybdenum, molybdenum nitride, or vanadium nitride. A particularly interesting class of materials for the first electrode base layer is the conductive metal nitrides. In some embodiments, the first electrode base layer includes titanium nitride. The first electrode base layer is typically formed using an ALD, CVD, or PVD technique. The first electrode base layer typically has a thickness between 5 nm and 50 nm, and preferably between 10 nm and 25 nm. In some embodiments, first electrode metal oxide layer (i.e. blocking layer or flash layer), 506, is formed above first electrode base layer, 504. Together, the first electrode base layer and the first electrode metal oxide layer form the first electrode layer of the capacitor stack. The metal oxide portion of the first electrode may be formed using an ALD process as discussed previously. The first electrode metal oxide layer typically has a thickness between 0.1 nm and 1.5 nm. In some embodiments, the first electrode metal oxide layer may include at least one of the compounds of cerium oxide, chromium oxide, europium oxide, iridium oxide, manganese oxide, molybdenum oxide, niobium oxide, ruthenium oxide, tin oxide, or tungsten oxide. Specific metal oxide materials of interest are the compounds of niobium oxide. The first electrode layer, (504 and 506), can be annealed to crystallize the layer.

In some embodiments, dielectric layer, 508, would then be formed above the first electrode metal oxide layer, 506. The dielectric layer is typically formed using an ALD, CVD, or PVD technique. The dielectric layer typically has a thickness between 5 nm and 10 nm, and preferably between 5 nm and 8 nm. A wide variety of dielectric materials have been targeted for use in DRAM capacitors. Examples of suitable dielectric materials include aluminum oxide, barium-strontium-titanate (BST), hafnium oxide, hafnium silicate, niobium oxide, lead-zirconium-titanate (PZT), a bilayer of silicon oxide and silicon nitride, silicon oxy-nitride, strontium-titanate (STO), tantalum oxide, titanium oxide, zirconium oxide or doped versions of the same. These dielectric materials may be formed as a single layer or may be formed as a hybrid or nanolaminate structure. In some embodiments, the dielectric layer includes zirconium oxide. In some embodiments, the dielectric layer includes doped zirconium oxide. Typical dopants for zirconium oxide include Al, Ce, Co, Er, Ga, Gd, Ge, Hf, In, La, Lu, Mg, Mn, Nd, Pr, Sc, Si, Sn, Sr, Ti, Y, or combinations thereof. Typically, dielectric layer, 608, is subjected to a PDA treatment before the formation of the second electrode layer as discussed previously.

The second electrode layer, 510, is formed above dielectric layer, 508. The second electrode layer may include a single layer or may include multiple layers as discussed previously. The second electrode layer is typically formed using an ALD, CVD, or PVD technique. The second electrode layer typically has a thickness between 5 nm and 50 nm, and preferably between 5 nm and 25 nm. The second electrode layer includes one of metals, conductive metal oxides, conductive metal nitrides, conductive metal silicides, conductive metal carbides, or combinations thereof. Optionally, the capacitor stack can then be subjected to a PMA treatment process in an reducing, natural, or oxidizing atmosphere, wherein the oxidizing atmosphere includes between 0% O₂ to 25% O₂ and at temperatures between 300 C to 600 C for between 1 millisecond to 60 minutes (not shown). Those skilled in the art will understand that other layers may be included in the capacitor stack.

Although the foregoing examples have been described in some detail for purposes of clarity of understanding, the invention is not limited to the details provided. There are many alternative ways of implementing the invention. The disclosed examples are illustrative and not restrictive.

1. A semiconductor layer stack comprising:
a first electrode base layer formed above a substrate;
wherein the first electrode base layer is a conducting layer, and
wherein the first electrode base layer is amorphous;
a first electrode metal oxide layer formed on the first electrode base layer,
wherein the first electrode metal oxide layer has a thickness between 1 A and 15 A and comprises niobium, and
wherein the first electrode base layer and the first electrode metal oxide layer form a first electrode;
a dielectric layer formed above the first electrode metal oxide layer; and
a second electrode layer formed above the dielectric layer.

2. The semiconductor layer stack of claim 1, wherein the first electrode base layer comprises one of ruthenium, platinum, titanium nitride, tantalum nitride, titanium-aluminum-nitride, tungsten, tungsten nitride, molybdenum, molybdenum nitride, or vanadium nitride.

3. The semiconductor layer stack of claim 1, wherein the first electrode metal oxide layer comprises niobium oxide.

4. The semiconductor layer stack of claim 1, wherein the dielectric layer comprises one of aluminum oxide, barium-strontium-titanate (BST), hafnium oxide, hafnium silicate, niobium oxide, lead-zirconium-titanate (PZT), a bilayer of silicon oxide and silicon nitride, silicon oxy-nitride, strontium-titanate (STO), tantalum oxide, titanium oxide, zirconium oxide or doped versions of the same.

5. The semiconductor layer stack of claim 4, wherein the dielectric layer comprises zirconium oxide or a doped version of the same.

6. The semiconductor layer stack of claim 5, wherein the dielectric layer further comprises a dopant comprising at least one of Al, Ce, Co, Er, Ga, Gd, Ge, Hf, In, La, Lu, Mg, Mn, Nd, Pr, Sc, Si, Sn, Sr, Y, or Zr.

7-11. (canceled)

12. The semiconductor layer stack of claim 1, wherein the second electrode layer comprises one of ruthenium, platinum, titanium nitride, tantalum nitride, titanium-aluminum-nitride, tungsten, tungsten nitride, molybdenum, molybdenum nitride, or vanadium nitride.

13. The semiconductor layer stack of claim 12, wherein the second electrode layer comprises titanium nitride.

14-15. (canceled)

16. The semiconductor layer stack of claim 1, wherein the first electrode base layer comprises titanium nitride, the first electrode metal oxide layer comprises niobium oxide, the dielectric layer compromises zirconium oxide, and the second electrode layer comprises titanium nitride.

17. The semiconductor layer stack of claim 1, wherein the first electrode base layer comprises titanium nitride, the first electrode metal oxide layer comprises niobium oxide, the dielectric layer compromises doped zirconium oxide, and the second electrode layer comprises titanium nitride.

18. The semiconductor layer stack of claim 17, wherein the dielectric layer further comprises a dopant comprising at least one of Al, Ce, Co, Er, Ga, Gd, Ge, Hf, In, La, Lu, Mg, Mn, Nd, Pr, Sc, Si, Sn, Sr, Y, or Zr.

19. The semiconductor layer stack of claim 1, wherein the dielectric layer has a thickness between about 5 nm and about 10 nm.

20. The semiconductor layer stack of claim 19, wherein the dielectric layer has a thickness between about 5 nm and about 8 nm.

21. The semiconductor layer stack of claim 1, wherein the second electrode layer has a thickness between about 5 nm and about 50 nm.

22. The semiconductor layer stack of claim 21, wherein the second electrode layer has a thickness between about 10 nm and about 25 nm.

23. The semiconductor layer stack of claim 16, wherein the niobium oxide of the first electrode metal oxide layer has a first k value and the dielectric layer has a second k value;
wherein the second k value is higher than the first k value; and
wherein the niobium oxide layer stabilizes the dielectric layer.

24. The semiconductor layer stack of claim 23, wherein the dielectric layer is a tetragonal phase of zirconium oxide.
